(19) United States
(12) Patent Application Publication
(10) Pub. No.: US 2013/0134837 A1
(43) Pub. Date: May 30, 2013

(54) DISK TYPE MEMS RESONATOR

(71) Applicants: Takefumi Saito, Tokyo (JP); Noritoshi Kimura, Tokyo (JP)

(72) Inventors: Takefumi Saito, Tokyo (JP); Noritoshi Kimura, Tokyo (JP)

(73) Assignee: NIHON DEMPA KOGYO CO., LTD., TOKYO (JP)

(21) Appl. No.: 13/814,738

(22) PCT Filed: Jun. 13, 2011
(86) PCT No.: PCT/JP2011/063991

§ 371 Date: Feb. 7, 2013

(30) Foreign Application Priority Data
Aug. 10, 2010 (JP) 2010-179495

(51) Int. Cl. H01L 41/047

(52) U.S. Cl. CPC H01L 41/047
USPC 310/365

(57) ABSTRACT

In order to provide complete removal of a sacrificial layer on a bottom surface of a disk during an etching process, without leaving residue, a disk type resonator of an electrostatic drive type includes a disk type resonator structure; a pair of drive electrodes at a predetermined gap from an outer peripheral portion of the disk type resonator structure and disposed at both sides of the resonator structure so as to face each other; a unit for applying an alternating current bias voltage with a same phase to the drive electrodes; and a detection unit that obtains an output corresponding to an electrostatic capacitance between the disk type resonator structure and the drive electrodes. The disk type resonator structure has a through hole in the center of the disk and is vibrated in a wineglass mode.

### TECHNICAL FIELD

This disclosure relates to a disk type resonator (a resonator) fabricated by MEMS. Especially, the disclosure relates to the resonator where a through-hole is formed at the center of a disk to allow etchant to easily penetrate into the bottom surface of the disk.

### BACKGROUND ART

As illustrated in FIG. 4, the conventional disk type MEMS resonator includes a disk-shaped vibrating unit (a disk) 10, drive electrodes 20, 20, a unit for applying an alternating current bias voltage (not shown), and detection electrodes 30, 30. The vibrating unit 10 is supported by the supporting portions 40, 40, which are protruded from the outer peripheral portion 10a of the vibrating unit 10. The drive electrodes 20, 20 are disposed at both sides of vibrating unit 10 having a predetermined gap g with respect to an outer peripheral portion 10a of the vibrating unit 10. The drive electrodes 20, 20 are opposed to each other. The unit applies an alternating current bias voltage with the same phase to the drive electrodes 20, 20. The detection electrodes 30, 30 obtain an output corresponding to an electrostatic capacitance between the vibrating unit 10 and the drive electrodes 20, 20.

This disk type resonator (the resonator) is fabricated by forming a silicon film on a semiconductor (silicon) substrate by Micro Electro Mechanical Systems (MEMS).
PATENT LITERATURE 1: Japanese Unexamined Patent Publication No. 2007-152501

NON-PATENT LITERATURE 1: M. A. Abdelmoneum, M. U. Demirci, and C. T.-O. Nguyen, “Stemless wine-glass-mode disk micromechanical resonators,” Proceedings, 16^{th} Int. IEEE Micro Electro Mechanical Systems Conf., Kyoto, Japan, Jan. 19-23, 2003, pp. 698-701

Non-Patent literature 2: W.-L. Huang, Z. Ren, and C. T.-C. Nguyen, “Nickel vibrating micromechanical disk resonator with solid dielectric capacitive-transducer gap,” Proceedings, 2006 IEEE Int. Frequency Control Symp., Miami, Fla., Jun. 5-7, 2006, pp. 839-847

### SUMMARY OF INVENTION

### Technical Problem

The method for fabricating this kind of the conventional disk type MEMS resonator includes the following process as the last process. A sacrifice layer, which has been formed at a prior process, is etched and removed by an etching process using hydrofluoric acid-based etchant (etching liquid) or similar process. A resonator structure (a disk type vibrating unit), which has already been formed, is separated from the drive electrodes and the detection electrodes. Further, the bottom surface of the resonator structure is separated from the semiconductor substrate, thus forming the resonator structure of an electrostatic resonator.

However, in a process where the sacrifice layer is wet-etched, an opening or similar is not formed on the disk surface. Accordingly, etchant does not sufficiently penetrate into the bottom surface of the disk, and the sacrifice layer on the bottom surface of the disk is difficult to be removed. This arises a problem that a part of the sacrifice layer remains as a residue.

### Solution to Problem

To solve the above-described problem with a disk type resonator of this disclosure, a disk type resonator of an electrostatic drive type includes a disk type resonator structure, a pair of drive electrodes, a unit, and a detection unit. The pair of drive electrodes are disposed opposite one another. The drive electrodes are disposed at both sides of the crystal resonator structure having a predetermined gap with respect to an outer peripheral portion of the disk type resonator structure. The unit is configured to apply an alternating current bias voltage with a same phase to the drive electrodes. The detection unit is configured to obtain an output corresponding to an electrostatic capacitance between the disk type resonator structure and the drive electrodes. The disk type resonator structure includes a disk with a through-hole at the center of the disk. The disk type resonator structure is vibrated in a wine glass mode.

In the disclosure, the through-hole have a transverse cross-sectional shape that is a square shape, a circular shape, a cross shape, or a rectangular shape.

In the disclosure, the through-hole have the transverse cross-sectional shape of the square shape, the cross shape, or the rectangular shape. The transverse cross-sectional shape has respective rounded corner portions.

In the disclosure, a radius of a circumscribed circle of each of the transverse cross-sectional shapes of the through-hole is set within a range from 1/20 to 1/10 relative to a radius of the disk.

In the disclosure, the crystal resonator structure is made of a monocrystalline silicon, a polycrystalline silicon, a monocrystalline diamond, or a polycrystalline diamond.

In the disclosure, the disk type resonator is fabricated by MEMS.

### Advantageous Effects of Disclosure

According to the present disclosure, a through-hole is formed at the center of the disk. This allows etchant to easily penetrate into the bottom surface of the disk via this through-hole at an etching process. This prevents generation of a residue of a sacrifice layer on the bottom surface of the disk, thus allowing complete removal of the sacrifice layer.

### BRIEF DESCRIPTION OF DRAWINGS

FIG. 1 is a conceptual structure diagram of a disk type MEMS resonator according to the disclosure.

FIGS. 2A to 2E illustrate transverse cross-sectional shapes of a through-hole formed at a center of a disk of the disk type MEMS resonator according to the disclosure: FIG. 2A illustrates a circular-shaped through-hole; FIG. 2B illustrates a square-shaped through-hole; FIG. 2C illustrates a cross-shaped through-hole; FIG. 2D illustrates a rectangular-shaped through-hole; and FIG. 2E illustrates an embodiment where a corner portion of the transverse cross-sectional shape of each through-hole illustrated in FIGS. 2A to 2D is rounded.

FIGS. 3A to 3F are views illustrating respective processes A to F of a method for fabricating the disk type MEMS resonator according to the disclosure. Each of steps in FIGS. 3A to 3F illustrates a step in the cross-sectional view indicated by the arrow of FIG. 1.

FIG. 4 is a conceptual structure diagram of the disk type MEMS resonator of a conventional example.

### DESCRIPTIONS OF REFERENCE NUMERAL

R disk type MEMS resonator (resonator)

1, 10 vibrating unit (disk)

2, 20 drive electrode

3, 30 detection electrode

4, 40 supporting portion

5 substrate

6 first insulating film

7 second insulating film

8 first conducting layer

9 sacrifice layer

10 vibrating unit

11 first oxidized film

12 second oxidized film

13 second conducting layer

### DESCRIPTION OF EMBODIMENTS

### Embodiment

### Disk Type MEMS Resonator

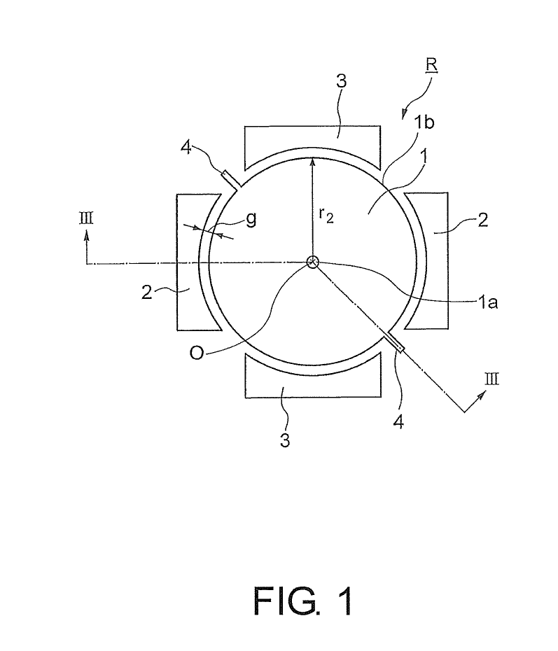

FIG. 1 is a conceptual structure diagram of a disk type MEMS resonator according to the present disclosure.

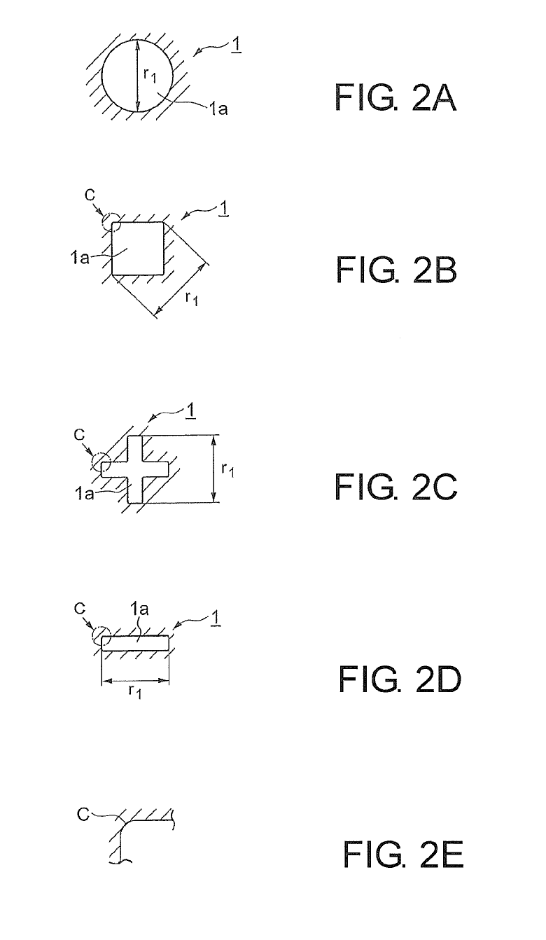

As illustrated in FIG. 1, a disk type MEMS resonator R according to the disclosure includes a disk-shaped vibrating unit (a disk; a resonator structure) 1, supporting portions 4, a pair of drive electrodes 2, 2, an alternating current power source (not shown), and a pair of detection electrodes 3,3. The disk-shaped vibrating unit 1 is made of an elastic body. The supporting portions 4 are protruded from an outer peripheral portion of the vibrating unit 1 and support the vibrating unit 1, for example, at two points. The pair of drive electrodes 2, 2 are disposed at both sides of the vibrating unit 1 having a predetermined gap g with respect to an outer peripheral portion 1a of the vibrating unit 1. The pair of drive electrodes 2, 2 are disposed opposite one another. The alternating current power source applies an alternating current bias voltage with the same phase to the pair of drive electrodes 2, 2. The pair of detection electrodes 3, 3 obtains an output corresponding to an electrostatic capacitance of the gap g between the vibrating unit 1 and the drive electrodes 2, 2. A through-hole 1a, with a transverse cross-sectional shape illustrated in each of FIGS. 2A to 2E, is formed at the center of the vibrating unit 1.

With this disk type MEMS resonator, when an electrical signal of a predetermined frequency is applied from the alternating current power source to the drive electrodes 2, 2, the vibrating unit (the disk) 1 vibrates at a predetermined frequency in a Wine-Glass-Vibrating-Mode by an electrostatic coupling. Additionally, the detection electrodes 3, 3 detect the electrical vibration of the vibrating unit 1 by the electrostatic coupling and then output the detected signal to a detector (not shown). Here, the center of this vibrating unit 1 and the supporting portions 4 at the two points (nodal points: nodes) do not vibrate.

The disclosure especially relates to the through-hole 1a formed penetrating through the center of the vibrating unit 1 where vibration does not occur during operation.

The disk-shaped vibrating unit 1 made of an elastic body, which is employed in the disclosure, is consist of a monocrystalline silicon, a polycrystalline silicon, a monocrystalline diamond, or a polycrystalline diamond.

The transverse cross-sectional shape of the through-hole 1a, which penetrate through the center of the disk type MEMS resonator 1 according to the disclosure, has a circular shape as illustrated in FIG. 2A, a square shape as illustrated in FIG. 2B, a cross shape as illustrated in FIG. 2C, or a rectangular shape as illustrated in FIG. 2D. As illustrated in FIG. 2E, each corner of the transverse cross-sectional shape of the square shape, the cross shape, and the rectangular shape may be rounded.

Further, it is assumed that a ratio of a radius r₁ of the circumscribed circle of each transverse cross-sectional shape of the through-hole 1a illustrated in FIGS. 2A to 2E with respect to a radius r₂ of the disk 1 is from 1/20 to 1/10.

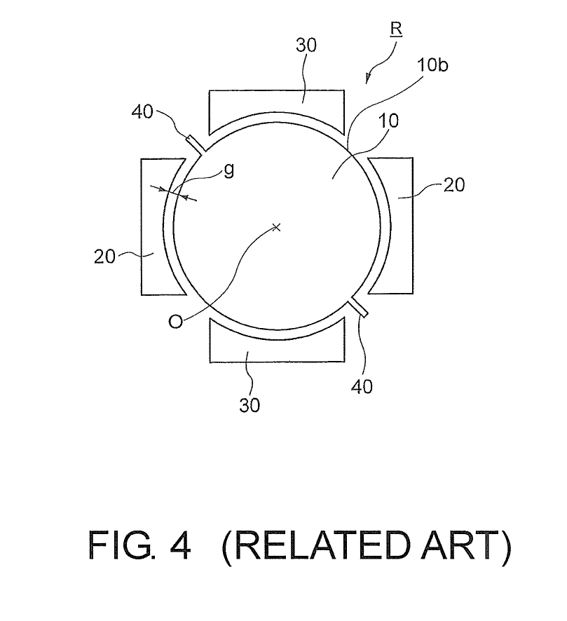

Table 1 lists the types of disk type MEMS resonator 1 that were constructed, according to the disclosure. Further, two types of disk type resonator of the conventional example that has a disk radius (r₂), a through-hole radius (r₁), and a disk thickness (t) (without the through-hole 1a, see FIG. 4) and two types of disk type resonator where a through-hole 1a with a radius r₁ of 2 μm is formed at the center of the disk (see FIG. 1) are prepared (disk type resonators (without a through-hole) A, B and disk type resonators (with a through-hole) A, B).

TABLE 1
Design dimensions of each model

| | r₂: Disk | r₁: Through hole | |
|---|---|---|---|
| Model Name | radius | radius | t: Disk thickness |
| Disk type resonator A | 27 μm | — | 2 μm |
| (without a through-hole) | | | |
| Disk type resonator B | 32 μm | — | 2 μm |
| (without a through-hole) | | | |
| Disk type resonator A | 27 μm | 2 μm | 2 μm |
| (with a through-hole) | | | |
| Disk type resonator B | 32 μm | 2 μm | 2 μm |
| (with a through-hole) | | | |

Then, a comparison is listed in Table 2 of an etching failure (a residue failure and over etching) occurrence rate in a removal process of the sacrifice layer. In this comparison, the disk type resonator without a through-hole (see FIG. 4) and the disk type resonator with a through-hole at the center (see FIG. 1) were employed, and a hundred chips were randomly sampled from each resonator. It is apparent from the table 2 that an etching defect rate including a residue failure of the sacrifice layer is drastically improved from 35% to 2% by the formation of the through-hole 1a at the center of the disk 1 as in the disclosure.

TABLE 2
Comparison of etching defect rate of each of the resonator shapes.

| | Etching defect rate |
|---|---|
| Disk type resonator (without a through-hole) | 35% |
| Disk type resonator (with a through-hole) | 2% |

As listed in table 3, a resonance characteristic was compared between the disk type resonator of the conventional example and the disk type resonator with a through-hole at the center using R₁ (motional resistance).

It is apparent from Table 3 that a deterioration in the resonance characteristic was not recognized even if the through-hole 1a of a circular transverse cross section, which has a radius r₁ of 2 μm (a ratio relative to the disk radius r₂ is from 1/10 to 1/20), is formed in each of the disk type resonators A and B with the radius of 27 μm and 32 μm listed in Table 1. On the other hand, it was confirmed that when the through-hole 1a with the radius r₁, which is outside the range of 1/10 to 1/20 relative to the disk radius r₂, was formed on the disk, the resonance characteristic was degraded.

TABLE 3
Comparison results of characteristics of each of the resonators

| | Resonance | R₁: Motional |
|---|---|---|
| Model Name | frequency | Resistance |
| Disk type resonator A (without a | 69.0 MHz | 1155 Ω |
| through-hole) | | |
| Disk type resonator B (without a | 58.2 MHz | 952 Ω |
| through-hole) | | |
| Disk type resonator A (with a | 66.7 MHz | 1144 Ω |
| through-hole) | | |
| Disk type resonator B (with a | 56.9 MHz | 945 Ω |
| through-hole) | | |

As seen from the above-described verification results, the formation of the through-hole 1a at center of the vibrating unit (the disk) 1 does not degrade the resonance characteristic of the disk type resonator. Further, etchant (etching liquid) easily penetrates into the bottom surface of the disk though the through-hole 1a at an etching process. This prevents generation of a residue of the sacrifice layer and allows obtaining a MEMS resonator (a resonator) with an excellent etching effect on removal of the sacrifice layer.

Method for Fabricating the Disk Type MEMS Resonator

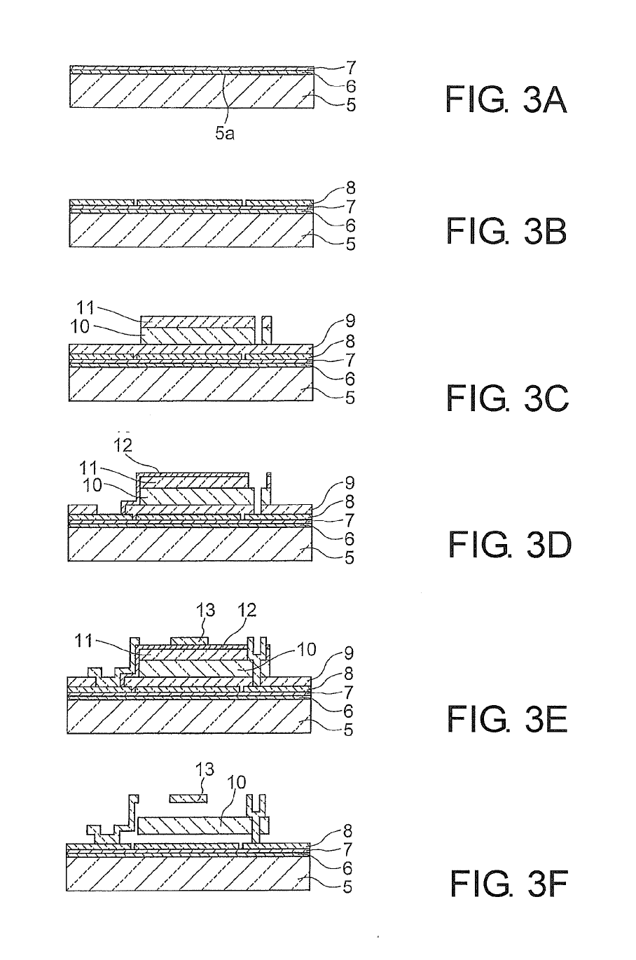

Next, a description will be given of a method for fabricating the disk type MEMS resonator by MEMS according to the present disclosure based on process views illustrated in FIGS. 3A to 3F.

First, as illustrated in FIG. 3A, a semiconductor substrate 5 made of Si is prepared. A first insulating film 6, which is made of phosphosilicate glass (PSG) or similar material, is formed on a surface 5a of the semiconductor substrate 5. Then, a second insulating film 7 made of a silicon nitride or similar material is formed on the surface of this first insulating film 6 by a method such as CVD (Chemical Vapor Deposition) or sputtering.

Next, as illustrated in FIG. 3B, a first conducting layer 8 is formed on the surface of the second insulating film 7 by a method such as CVD or sputtering. The first conducting layer 8 is made of a polysilicon film (Doped poly-Si) or similar material where phosphorus or boron is doped for adding a conductive property. Then, patterning with a patterning process that includes a formation process of a patterning mask and an etching process using this patterning mask is performed. The patterning mask is formed by resist coating, exposure, and development. Thus, portions on which the respective pairs of drive electrodes 2 and detection electrodes 3 in predetermined shapes are to be disposed are formed on the first conducting layer 8.

Further, as illustrated in FIG. 3C, a sacrifice layer 9 made of a phosphosilicate glass (PSG) or similar material is formed on the surface of the conducting layer 8 by a method such as CVD or sputtering. A conducting layer 10 made of a polysilicon film (Doped poly Si) or similar material is formed on the surface of the sacrifice layer 9 by a method such as CVD. A first oxidized film 11 made of non-doped-silicate-glass (NSG) is formed on the surface of the conducting layer 10 by a method such as CVD or sputtering. Then, similar to the above-described process, the patterning process is performed to form a disk-shaped resonator structure. At the same time, a through-hole with a predetermined dimension is formed at the center of the resonator structure by etching or similar method. In this process C, the surface of the sacrifice layer 9 may be flattened by a method such as chemical mechanical polishing (CMP).

Next, as illustrated in FIG. 3D, a second oxidized film 12 made of non-doped-silicate-glass (NSG) is formed on the surface of the first oxidized film 11 by a method such as CVD or sputtering, and the patterning process similar to the above-described process is performed.

Further, as illustrated in FIG. 3E, a second conducting layer 13 made of a polysilicon film where phosphorus or similar material is doped is formed on the surface of the second oxidized film 12 by a method such as CVD or sputtering. Then, the patterning process similar to the above-described process is performed to form the drive electrodes 2 and the detection electrodes 3.

Finally, as illustrated in FIG. 3F, the sacrifice layer 9, the first oxidized film 11, and the second oxidized film 12 are removed by an etching process using hydrofluoric acid-based etchant or similar method. This separates the conducting layer 10 (the resonator structure constitution layer) from the drive electrodes 2 and the detection electrodes 3. In the above-described process, the through-hole, which has a predetermined shape and dimensions and passes through from the top surface to the bottom surface of the conducting layer 10, is formed. This allows etchant to penetrate into the bottom surface of the conducting layer 10, sufficiently etch the bottom surface of the conducting layer 10, and remove the residue of the sacrifice layer 9. Then, the bottom surface of the conducting layer 10 is separated from the top surface of the substrate 5, thus fabricating a resonator structure R (a disk type MEMS resonator).

### INDUSTRIAL APPLICABILITY

A disk type MEMS resonator according to the present disclosure is widely applicable to a device such as a resonator, a SAW(Surface Acoustic Wave) device, a sensor, and an actuator.

1. A disk type resonator, which is an electrostatic drive type disk type resonator, comprising:
a disk type resonator structure;
a pair of drive electrodes disposed opposite one another, the drive electrodes being disposed at both sides of the resonator structure having a predetermined gap with respect to an outer peripheral portion of the disk type resonator structure;
a unit configured to apply an alternating current bias voltage with a same phase to the drive electrodes; and
a detection unit configured to obtain an output corresponding to an electrostatic capacitance between the disk type resonator structure and the drive electrodes, wherein
the disk type resonator structure includes a disk with a through-hole at the center of the disk, thereby
vibrating the disk type resonator structure in a wine glass mode.

2. The disk type resonator according to claim 1, wherein
the through-hole has a transverse cross-sectional shape that is a square shape, a circular shape, a cross shape, or a rectangular shape.

3. The disk type resonator according to claim 2, wherein
the through-hole has the transverse cross-sectional shape of the square shape, the cross shape, or the rectangular shape, and
the transverse cross-sectional shape has respective rounded corner portions.

4-6. (canceled)

7. The disk type resonator according to claim 1, wherein
a radius of a circumscribed circle of each of the transverse cross-sectional shapes of the through-hole is set within a range from 1/20 to 1/10 relative to a radius of the disk.

8. The disk type resonator according to claim 2, wherein
a radius of a circumscribed circle of each of the transverse cross-sectional shapes of the through-hole is set within a range from 1/20 to 1/10 relative to a radius of the disk.

9. The disk type resonator according to claim 3, wherein
a radius of a circumscribed circle of each of the transverse cross-sectional shapes of the through-hole is set within a range from 1/20 to 1/10 relative to a radius of the disk.

10. The disk type resonator according to claim 1, wherein
the resonator structure is made of a monocrystalline silicon, a polycrystalline silicon, a monocrystalline diamond, or a polycrystalline diamond.

11. The disk type resonator according to claim 2, wherein
the resonator structure is made of a monocrystalline silicon, a polycrystalline silicon, a monocrystalline diamond, or a polycrystalline diamond.

12. The disk type resonator according to claim 3, wherein
the resonator structure is made of a monocrystalline silicon, a polycrystalline silicon, a monocrystalline diamond, or a polycrystalline diamond.

13. The disk type resonator according to claim 7, wherein
the resonator structure is made of a monocrystalline silicon, a polycrystalline silicon, a monocrystalline diamond, or a polycrystalline diamond.

14. The disk type resonator according to claim 8, wherein
the resonator structure is made of a monocrystalline silicon, a polycrystalline silicon, a monocrystalline diamond, or a polycrystalline diamond.

15. The disk type resonator according to claim 9, wherein
the resonator structure is made of a monocrystalline silicon, a polycrystalline silicon, a monocrystalline diamond, or a polycrystalline diamond.

16. The disk type resonator according to claim 1, wherein
the disk type resonator is fabricated by MEMS.

17. The disk type resonator according to claim 2, wherein
the disk type resonator is fabricated by MEMS.

18. The disk type resonator according to claim 7, wherein
the disk type resonator is fabricated by MEMS.

19. The disk type resonator according to claim 10, wherein
the disk type resonator is fabricated by MEMS.
